(19) United States
(12) Patent Application Publication
(10) Pub. No.: US 2026/0247678 A1
(43) Pub. Date: Aug. 20, 2026

(54) METHOD OF FORMING A METAL SILICIDE FILM

(71) Applicant: ASM IP Holding B.V., Almere (NL)

(72) Inventors: Sisi Wang, Phoenix, AZ (US); Wei Li, Chandler, AZ (US); Mojtaba Samiee, Tempe, AZ (US); Balaji Kannan, Phoenix, AZ (US); Jonathan Bakke, Phoenix, AZ (US)

(21) Appl. No.: 19/540,869

(22) Filed: Feb. 16, 2026

Related U.S. Application Data
(60) Provisional application No. 63/760,419, filed on Feb. 19, 2025.

(51) Int. Cl. H10D 64/01; C23C 16/18; H10P 14/60

(52) U.S. Cl. CPC H10D 64/0112; C23C 16/18; H10P 14/6339

(57) ABSTRACT

Methods for forming a metal silicide are disclosed. An exemplary method includes providing a substrate in a reaction chamber, performing a thermal deposition process to form a metal silicide film, and optionally forming a cap layer (e.g., directly) on the metal silicide. Exemplary method can further include performing a soak process. Methods described herein may be performed without generating a plasma.

### CROSS-REFERENCE TO RELATED APPLICATIONS

This application is a nonprovisional of, and claims priority to and the benefit of, U.S. Provisional Patent Application No. 63/760,419, filed Feb. 19, 2025 and entitled “METHOD OF FORMING A METAL SILICIDE FILM,” which is hereby incorporated by reference herein.

### FIELD

The disclosure generally relates to methods of and apparatuses for forming electronic devices. More particularly, examples of the disclosure relate to a method for forming a metal silicide film, to a structure comprising a metal silicide film, and a substrate processing apparatus for forming a metal silicide film.

### BACKGROUND

Metal silicide layers are used in a wide variety of electronic devices, such as semiconductor devices. However, the formation of metal silicides on certain surfaces has proven challenging. Conventional methods of forming metal silicides have often used plasma-enhanced process, which may have drawbacks including low selectively, low conformality of films, and damage to other layers. Accordingly, there exists a desire for improved methods of and apparatuses for depositing metal silicides on a range of surfaces on a substrate.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Various examples described herein relate to methods for forming a metal silicide film. As set forth below, methods described herein may be used in the fabrication of electronic devices, such as semiconductor devices. Methods as described herein use non-plasma or thermal deposition processes to form metal silicides on a variety of surfaces, including surfaces that, to date, have been difficult to grow metal silicides on without plasma processes.

According to one or more embodiments, a method of forming a metal silicide film is provided. An exemplary method includes providing a substrate in a reaction chamber, performing a thermal deposition process to form a metal silicide film, and optionally forming a cap layer (e.g., directly) on the metal silicide. The method can further include performing a soak process. In some embodiments, the method of forming the metal silicide film does not expose the substrate to a plasma, or to excited species generated from a plasma.

In accordance with examples of the disclosure, performing a soak process comprises providing an organic aluminum reactant to the reaction chamber.

In accordance with examples of the disclosure, the thermal deposition process comprises a cyclical deposition process, such as an atomic layer deposition process. In accordance with particular examples, a cycle of the cyclical deposition process includes the following steps, and in some embodiments, in the order of: 1) pulsing a first metal precursor, 2) pulsing a first silicon precursor, and 3) providing the organic aluminum reactant.

In accordance with examples of the disclosure, the organic aluminum reactant (i.e., the organic aluminum reactant provided in the soak process or the cyclical deposition process) includes aluminum and carbon. In some embodiments, the organic aluminum reactant is represented by the formula Al(R)₃, wherein each R is independently selected from H and C1-C6 alkyl groups. In some embodiments, each R is independently selected from C1-C6 alkyl groups. By way of examples, the organic aluminum reactant can be or include triethylaluminum, trimethylaluminum, tris-isobutylaluminum, or tris-tert-butylaluminum. In some embodiments, relatively low amounts of species or components of the organic aluminum reactant are incorporated into the metal silicide film.

In accordance with further examples of the disclosure, a device is formed using a method and/or include a structure as described herein.

In accordance with yet further exemplary embodiments of the disclosure, a system is provided for performing a method and/or for forming a structure as described herein.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWINGS

FIG. 1 illustrates a method for forming a metal silicide film in accordance with one or more embodiments of the disclosure;

FIG. 2 illustrates a method for performing a thermal deposition process in accordance with one or more embodiments of the disclosure;

FIG. 3 illustrates another method for performing a thermal deposition process in accordance with one or more embodiments of the disclosure;

FIG. 4 illustrates another embodiment of a method for forming a metal silicide film in accordance with one or more embodiments of the disclosure;

FIG. 5 illustrates another method for performing a thermal deposition process in accordance with one or more embodiments of the disclosure;

FIG. 6 illustrates an example of a substrate processing apparatus in accordance with one or more examples of the disclosure;

FIG. 7 illustrates an example of a structure that can form part of a device in accordance with one or more examples of the disclosure; and

FIG. 8 illustrates another example of a structure that can form part of a device in accordance with one or more examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and systems provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the singular forms “a,” “an,” and “the” are intended to include the singular and plural forms as well, unless the context indicates otherwise.

As used herein, the term “substrate” can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as Group III-V or Group II-VI semiconductors, and can include one or more layers overlying or underlying the bulk material. By way of example, a substrate can include silicon or silicon germanium.

The terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate to form a film as disclosed herein. A reactant may be an element or a compound that is not incorporated into the resulting compound or element to a significant extent. In some cases, the term reactant can be used interchangeably with the term precursor.

As used herein, a “silicon precursor” includes a gas or a material that can become gaseous and that can be represented by a chemical formula that includes silicon.

As used herein, a “metal precursor” includes a gas or a material that can become gaseous and that can be represented by a chemical formula that includes one or more metals.

In some embodiments, “film” refers to a layer extending in a direction perpendicular to a thickness direction. In some embodiments, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles.

As used herein, the term “purge” can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be affected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

As used herein, the term “structure” can refer to a partially or completely fabricated device structure. By way of examples, a structure can be a substrate or include a substrate with one or more layers and/or features formed thereon.

As used herein, the term “overlying” can refer to two films in (e.g., direct) contact with each other.

As used herein, the term “cyclical deposition process” or “cyclic deposition process” can refer to a vapor deposition process in which deposition cycles, typically a plurality of consecutive deposition cycles, are conducted in a process chamber. Cyclic deposition processes can include, for example, cyclic chemical vapor deposition (CCVD) and/or atomic layer deposition (ALD) processes.

In this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. For example, values of variables may include +/−20%, or +/−10%, or +/−5%, or +/−1%, or +/−0% of the value of the listed variable. Further, in this disclosure, the terms “comprising,” “including,” “constituted by” and “having” can refer independently to “typically or broadly comprising,” “comprising,” “consisting essentially of,” or “consisting of” in some embodiments. In this disclosure, any defined meanings do not necessarily exclude ordinary and customary meanings in some embodiments.

A carrier and/or inert gas can be (e.g., continuously) co-flowed throughout any steps or sub-steps of any methods described herein. By way of example, a carrier and/or an inert gas can be one or more of helium, argon, or nitrogen.

Various steps of methods described herein can be performed within a single reaction chamber or can be performed in multiple reaction chambers, such as reaction chambers of a cluster tool. In some embodiments, the methods may take place in a single reaction space. In some embodiments, one or more steps or substeps of methods described herein may take place in a different reaction space or a different reaction chamber.

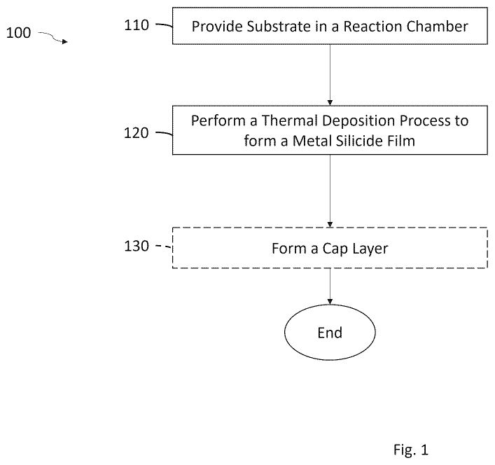

FIG. 1 illustrates a method 100 for forming a metal silicide film in accordance with exemplary embodiments of the disclosure. Method 100 includes providing a substrate within a reaction chamber (step 110), performing a thermal deposition process to form a metal silicide film (step 120), and optionally forming a cap layer (step 130). As noted above, the method 100 may be a thermal process (i.e., no plasma is generated and/or the substrate is not exposed to a plasma or species generated by a plasma during the method 100).

During step 110, a substrate is provided into a reaction space in a reaction chamber. In accordance with examples of the disclosure, the reaction chamber can form part of a chemical vapor deposition reactor, such as a chemical vapor deposition (CVD) reactor, an atomic layer deposition (ALD) reactor, or the like.

During step 110, the substrate can be brought to a desired temperature and/or the reaction space can be brought to a desired pressure, such as a temperature and/or pressure suitable for subsequent steps. By way of examples, a temperature (e.g., of a substrate, a substrate support, or an environment) within a reaction space can be between about 0° C. and about 500° C., or between about 250° C. and about 425° C. By way of examples, a pressure within a reaction space can be less than 760 torr, or between about 1 torr and 500 torr, or between about 1 torr and about 100 torr.

In some embodiments, the surface of the substrate comprises one or more of a metal oxide, a high-k dielectric (e.g., a dielectric with a dielectric constant greater than silicon oxide), a metal nitride, silicon oxide, silicon nitride, and a semiconductor, such as silicon or the like. By way of examples, the surface of the substrate comprises one or more of silicon, silicon germanium, hafnium oxide, titanium oxide, silicon oxide, titanium nitride, and silicon nitride.

The method 100 continues with performing a thermal deposition process to form a metal silicide film 120. In some embodiments, the metal silicide film is formed directly on the surface of the substrate comprising a metal oxide, a metal nitride, silicon oxide, silicon nitride, or silicon. The thermal deposition process uses thermal energy to drive the chemical change and deposit a metal silicide film. In some embodiments, the substrate may not be exposed to a plasma or species generated by a plasma during the thermal deposition process. In some embodiments, performing a thermal deposition process comprises a cyclical deposition process, such as an atomic layer deposition (ALD) process or a cyclical CVD process.

In some embodiments, a thickness of the metal silicide film is between about 10 Angstroms and about 300 Angstroms, or between about 15 Angstroms and about 50 Angstroms, or between about 20 Angstroms and about 30 Angstroms.

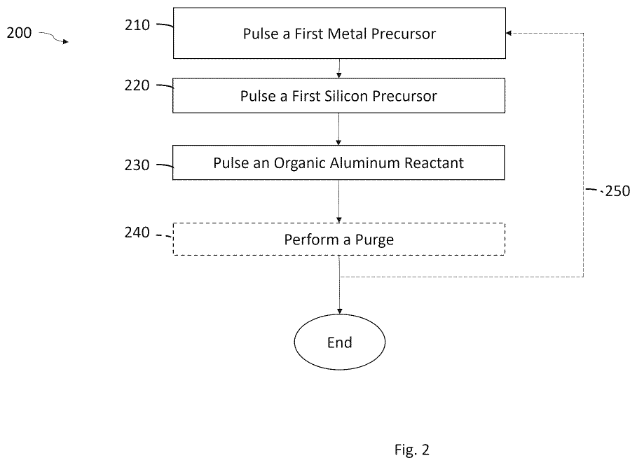

FIG. 2 illustrates a method 200 suitable for step 120 in FIG. 1. Method 200 comprises pulsing a first metal precursor 210, pulsing a first silicon precursor, pulsing an organic aluminum reactant 230, optionally performing a purge 240, and optionally repeating the steps one or more times (loop 250). In some cases, the sub-steps 210-240 of method 200 may be performed in any order. In an exemplary embodiment, the sub-steps 210-230 of method 200 are performed in the order of 1) pulsing a first metal precursor 210, 2) pulsing a first silicon precursor 220, and 3) pulsing an organic aluminum reactant 230. Each sub-step 210-240 of method 200 may be performed once or a plurality of times before proceeding to the next step. In some embodiments, a purge, such as purge 240, is performed after any or all of the sub-steps 210-230 of pulsing a first metal precursor 210, pulsing a first silicon precursor 220, and pulsing an organic aluminum reactant 230.

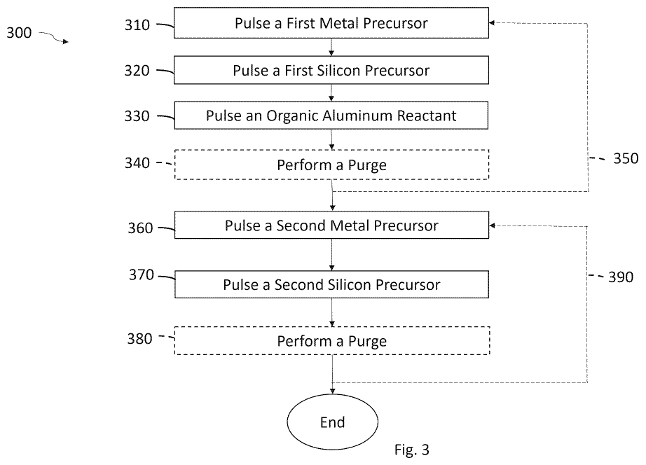

FIG. 3 illustrates another method 300 suitable for step 120 in FIG. 1. Method 300 comprises pulsing a first metal precursor 310, pulsing a first silicon precursor 320, pulsing an organic aluminum reactant 330, optionally, performing a purge 340, and optionally repeating the steps one or more times (loop 350). In an exemplary embodiment, loop 350 is performed about 2 to 5 times. The sub-steps 310-340 of method 300 may be performed in any order. In an exemplary embodiment, the sub-steps of method 300 are performed in the order of 1) pulsing a first metal precursor 310, 2) pulsing a first silicon precursor 320, and 3) pulsing an organic aluminum reactant 330. Performing the steps in this order mitigates initial formation of the layer or film on the surface of the substrate. Each sub-step 310-340 of method 300 may be performed once or a plurality of times before proceeding to the next step. In some embodiments, a purge, such as purge 340, is performed after any or all of the sub-steps 310-330 of pulsing a first metal precursor 310, pulsing a first silicon precursor 320, and pulsing an organic aluminum reactant 330. In some embodiments, sub-steps 310-350 may form a nucleation layer of a metal silicide (e.g., directly) on the surface of the substrate. In some embodiments, the nucleation layer may have a thickness in the range of about 1 Angstrom to 20 Angstroms, or about 3 Angstroms to about 15 Angstroms, or about 5 Angstroms to about 13 Angstroms.

Method 300 continues with pulsing a second metal precursor 360, pulsing a second silicon precursor 370, optionally performing a purge 380, and optionally repeating the steps one or more times (loop 390). In some embodiments, sub-steps 360-390 form a bulk layer of metal silicide (e.g., directly) on the nucleation layer. In some embodiments, the bulk layer may have a thickness in the range of about 10 Angstroms to 280 Angstroms, or about 15 Angstroms to about 40 Angstroms, or about 20 Angstroms to 30 Angstroms. The sub-steps 360-380 of method 300 may be performed in any order. Each sub-step 360-380 of method 300 may be performed once or a plurality of times before proceeding to the next step. In some embodiments, a purge, such as purge 380, is performed after any or all of the sub-steps 360-370 of pulsing a second metal precursor 360 and pulsing a second silicon precursor 370.

The first metal precursor that is provided during steps 210 and/or 310 may be any suitable precursor comprising one or more metals. In some embodiments, the first metal precursor does not comprise aluminum. In some embodiments, the first metal precursor comprises a metal halide or a metalorganic compound. In some embodiments, the first metal precursor comprises one or more of Nb, Ti, Mo, Ni, Co, W, Hf, Ta, or V. By way of examples, the first metal precursor may be NbCl₅, TiCl₄, WCl₆, MoCl₅, or VCl₅.

The second metal precursor that is provided during a step 360 may be any suitable precursor comprising one or more metals. In some embodiments, the second metal precursor does not comprise aluminum. In some embodiments, the second metal precursor comprises a metal halide or a metalorganic compound. In some embodiments, the second metal precursor comprises one or more of Nb, Ti, Mo, Ni, Co, W, Hf, Ta, or V. By way of examples, a second metal precursor may be NbCl₅, TiCl₄, WCl₆, MoCl₅, or VCl₅. In some embodiments, the first metal precursor comprises the same metal as the second metal precursor. In some embodiments, the first metal precursor is the same as the second metal precursor.

The first silicon precursor provided during steps 220 and/or 320 may be any suitable precursor comprising silicon. In some embodiments, the first silicon precursor comprises a silane or a chlorosilane. By way of examples, a first silicon precursor may be silane (SiH₄), disilane, trisilane, SiCl₄, chlorosilane (SiCl₄), dichlorosilane, or trichlorosilane.

The second silicon precursor provided during steps 370 may be any suitable precursor comprising silicon. In some embodiments, the second silicon precursor comprises a silane or a chlorosilane. By way of examples, a first silicon precursor may be silane (SiH₄), disilane, trisilane, SiCl₄, chlorosilane (SiCl₄), dichlorosilane, or trichlorosilane. In some embodiments, the first silicon precursor is the same as the second silicon precursor.

The organic aluminum reactant provided during any of the steps 230 and 330 may be any suitable reactant comprising carbon and aluminum. In some embodiments, the organic aluminum reactant comprises at least one Al—C bond. In some embodiments, the organic aluminum reactant is represented by the formula Al(R)₃, wherein each R is independently selected from H and C1-C6 alkyl groups. In some embodiments, each R is independently selected from C1-C6 alkyl groups. By way of particular examples, the organic aluminum reactant can be or include triethylaluminum, trimethylaluminum, tris-isobutylaluminum, or tris-tert-butylaluminum.

Not to be bound by theory, the organic aluminum reactant may act to initiate the deposition process or initiate a nucleation layer on a surface where growing a metal silicide is difficult or cannot be otherwise achieved without a plasma-enhanced deposition process. As a reactant, relatively low amounts of organic aluminum reactant, or constituent elements of the organic aluminum reactant, may be incorporated into the metal silicide film. Additionally, species or components of the precursors used in depositing the metal silicide film may react to from gaseous aluminum-containing compounds, which may be removed from the chamber in a purge. For example, when a metal halide is used as a precursor, gaseous aluminum chloride may be formed and removed from the reaction chamber, such that aluminum is not incorporated into the metal silicide film. The metal silicide film may comprise less than 7 at % aluminum, or less than 5 at % aluminum, or less than 3 at % aluminum, or less than 2 at % aluminum. Further, the metal silicide films as deposited may maintain relatively low resistivities. In some embodiments, the metal silicide film has a resistivity of less than 1000 μΩ cm, or less than 500 μΩ cm, or less than 350 μΩ cm, less than 275 μΩ cm, or between about 240 μΩ cm and about 270 μΩ cm.

Turning back to FIG. 1, method 100 may continue with optionally forming a cap layer 130. In some embodiments, the cap layer may be a metal nitride. By way of examples, the cap layer may be a titanium nitride or a silicon-doped titanium nitride. The cap layer may be formed by any suitable method, including a cyclical deposition process. In some embodiments, the cap layer is formed by a thermal process.

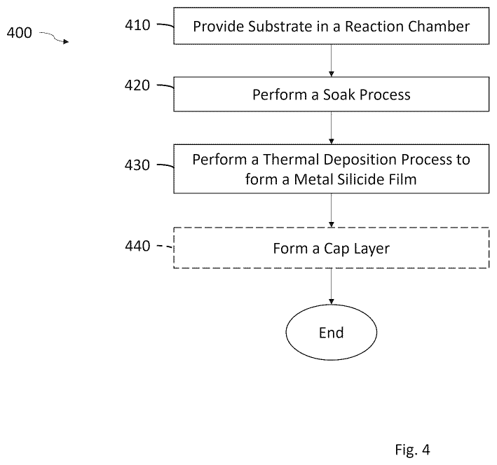

FIG. 4 illustrates another exemplary method 400 for forming a metal silicide film in accordance with exemplary embodiments of the disclosure. Method 400 includes the step of providing a substrate within a reaction chamber (step 410), performing a soak process (step 420), performing a thermal deposition process to form a metal silicide film (step 430), and optionally forming a cap layer (step 440). The method 400 may be a thermal process (i.e., no plasma is generated and/or the substrate is not exposed to a plasma or species generated by a plasma during the method 400).

During step 410, a substrate is provided into a reaction space in a reaction chamber. In accordance with examples of the disclosure, the reaction chamber can form part of a chemical vapor deposition reactor, such as a chemical vapor deposition (CVD) reactor, an atomic layer deposition (ALD) reactor, or the like. Various steps of methods described herein can be performed within a single reaction chamber or can be performed in multiple reaction chambers, such as reaction chambers of a cluster tool.

During step 410, the substrate can be brought to a desired temperature and/or the reaction space can be brought to a desired pressure, such as a temperature and/or pressure suitable for subsequent steps. By way of examples, a temperature (e.g., of a substrate, a substrate support, or an environment) within a reaction space can be between about 0° C. and about 500° C., or between about 250° C. and about 425° C. By way of examples, a pressure within a reaction space can be less than 760 torr, or between about 1 torr and 500 torr, or between about 1 torr and about 100 torr.

Method 400 continues with performing a soak process 420. The soak process 420 comprises providing an organic aluminum reactant to the reaction chamber. In accordance with examples of the disclosure, the soak process comprises providing the organic aluminum reactant to the reaction chamber while not removing the organic aluminum reactant with a removal pump or reducing a removal rate (e.g., by closing valves for gas removal) for a load period LP. This results in a pressure buildup of the organic aluminum reactant in the reaction chamber. This build up may be terminated when the pressure in the reaction chamber reaches a desired pressure. Alternatively, there may be a pressure release valve that opens when the pressure in the reaction chamber increases above a predetermined maximum, which may also end the pressure load period LP.

Subsequently, the organic aluminum reactant may be maintained residing stationary in the reaction chamber while not providing or removing any catalyst for a soak period SP. This may be done by closing reactor chamber valves. When the reaction chamber is constructed and arranged to accommodate a single substrate, the load period LP can be between 1 and 3000 seconds, between 3 and 1000 seconds, or between 5 and 500 seconds; and the soak period SP can be between 10 and 9000 seconds, between 50 and 5000 seconds, or between 100 and 1000 seconds. In some cases, a flowrate of gas from the reaction chamber to a vacuum source during the soak period is less than a flowrate of gas from the reaction chamber to the vacuum source during forming a metal silicide film. During the soak process, the organic aluminum reactant may react with a surface of the substrate. The organic aluminum reactant can be purged from the reaction chamber (e.g., during a flush period or in subsequent purges in subsequent steps.) The organic aluminum reactant may be any organic aluminum reactant as described herein.

Method 400 continues with performing a thermal deposition process to form a metal silicide film. During step 120, the substrate can be brought to a desired temperature and/or the reaction space can be brought to a desired pressure. By way of examples, a temperature (e.g., of a substrate or a substrate support) within a reaction space can be between about 200° C. and about 500° C., or between about 250° C. and about 425° C. A pressure within the reaction chamber can also be controlled. By way of examples, a pressure within a reaction space can be less than 760 torr, or between about 1 torr and 100 torr. In some embodiments, the metal silicide film is formed directly on the surface of the substrate comprising a metal oxide, a metal nitride, silicon oxide, silicon nitride, or bare silicon.

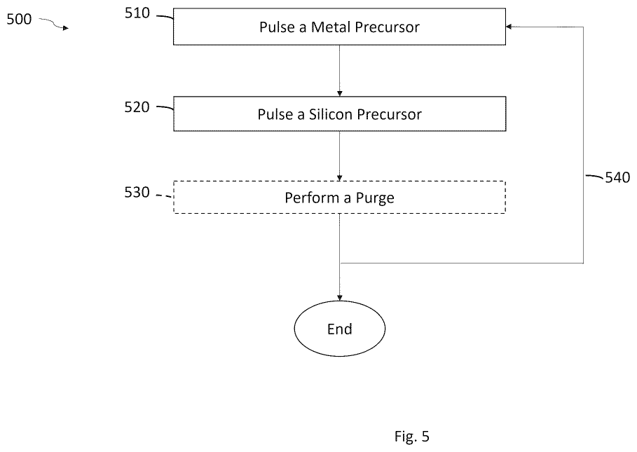

FIG. 5 illustrates a method 500 suitable for step 430 in FIG. 4. Method 500 comprises pulsing a first metal precursor 510, pulsing a first silicon precursor 520, and, optionally, performing a purge 530, and optionally repeating the steps one or more times (loop 540). The sub-steps 510-530 of method 500 may be performed in any order. Each sub-step 510-530 of method 500 may be performed once or a plurality of times before proceeding to the next step. In some embodiments, a purge, such as purge 530, is performed after any or all of the sub-steps 510-520 of pulsing a first metal precursor 510 and pulsing a first silicon precursor 520. The first metal precursor of method 500 may be any metal precursor as described herein. The first silicon precursor of method 500 may be any silicon precursor as described herein.

Turning back to FIG. 4, method 400 continues with optionally forming a cap layer 440. Forming a cap layer 440 may be identical or substantially similar to the step of forming a cap layer 130.

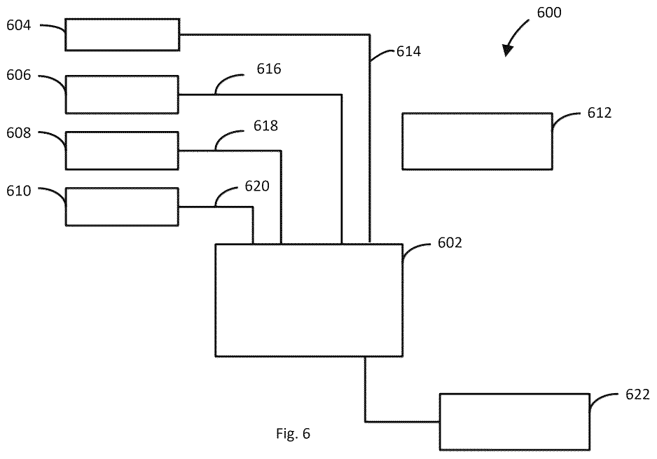

FIG. 6 illustrates an example of a substrate processing apparatus 600 in accordance with one or more examples of the disclosure. Apparatus 600 can be used to perform a method as described herein and/or form a structure or device portion as described herein.

In the illustrated example, apparatus 600 includes one or more reaction chambers 602, a metal precursor gas source 604, a silicon precursor gas source 606, an organic aluminum reactant gas source 608, an inert gas source 610, an exhaust source 622, and a controller 612.

Reaction chamber 602 can include any suitable reaction chamber, such as an atomic layer deposition (ALD) or chemical vapor deposition (CVD) reaction chamber.

Metal precursor gas source 604 can include a vessel and one or more metal precursors as described herein-alone or mixed with one or more carrier (e.g., inert) gases. Silicon precursor gas source 606 can include a vessel and one or more silicon precursors as described herein-alone or mixed with one or more carrier (e.g., inert) gases. Organic aluminum reactant gas source 608 can include a vessel and one or more of organic aluminum reactants as described herein-alone or mixed with one and/or more carrier gases. Inert gas source 610 can include a vessel and one and/or more inert gases, such as nitrogen, helium, or argon. Although illustrated with four gas sources 604-610, apparatus 600 can include any suitable number of gas sources. Gas sources 604-610 can be coupled to reaction chamber 602 via lines 614-620, which can each include flow controllers, valves, heaters, and the like.

Exhaust source 622 can include one or more vacuum pumps.

Controller 612 includes electronic circuitry and software to selectively operate valves, manifolds, heaters, pumps, and other components included in the apparatus 600. Such circuitry and components operate to introduce precursors, reactants, and gases from the respective sources 604-610. Controller 612 can control timing of gas pulse sequences, temperature of the substrate and/or reaction chamber, pressure within the reaction chamber, and various other operations to provide proper operation of the apparatus 600. Controller 612 can include control software to electrically or pneumatically control valves to control flow of precursors, reactants, and purge gases into and out of the reaction chamber 602. Controller 612 can include modules such as a software or hardware component, e.g., a FPGA or ASIC, which performs certain tasks. A module can advantageously be configured to reside on the addressable storage medium of the control system and be configured to execute one or more processes or methods, as described herein.

Other configurations of apparatus 600 are possible, including different numbers and kinds of precursor and reactant sources and purge gas sources. Further, it will be appreciated that there are many arrangements of valves, conduits, precursor sources, and purge gas sources that may be used to accomplish the goal of selectively feeding gases into reaction chamber 602. Further, as a schematic representation of a system, many components have been omitted for simplicity of illustration, and such components may include, for example, various valves, manifolds, purifiers, heaters, containers, vents, and/or bypasses.

During operation of apparatus 600, substrates, such as semiconductor wafers (not illustrated), are transferred from, e.g., a substrate handling system to reaction chamber 602. Once substrate(s) are transferred to reaction chamber 602, one or more gases from gas sources 604-610, such as precursors, reactants, carrier gases, and/or purge gases, are introduced into reaction chamber 602.

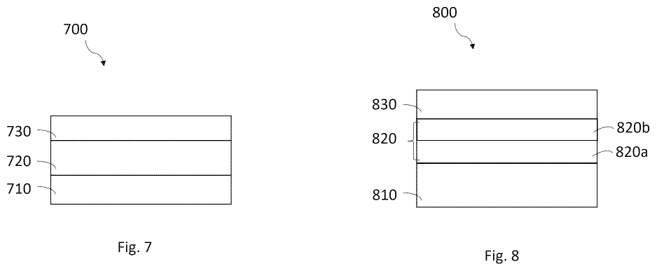

FIG. 7 illustrates a structure/a portion of a device 700 in accordance with additional examples of the disclosure. Device or structure 700 includes a substrate 710, a metal silicide film 720, and a cap layer 730. The substrate 710 may comprise a metal oxide, a metal nitride, silicon oxide, silicon nitride, or silicon. By way of examples, the surface of the substrate comprises silicon, silicon oxide, titanium nitride, or silicon nitride. The metal silicide film 720 may be formed by a method described in this disclosure. In some embodiments, the metal silicide film 620 comprises a silicide of Nb, Ti, Mo, Ni, Co, W, Hf, Ta, or V. The metal silicide film 620 may have a thickness between about 10 Angstroms to 300 Angstroms, or between about 15 Angstroms and about 50 Angstroms, or between about 20 Angstroms and about 30 Angstroms. The metal silicide may be disposed directly on the metal oxide, a metal nitride, silicon oxide, silicon nitride, or silicon of the substrate 710. The cap layer 730 may be formed by a method described in this disclosure. In some embodiments, the cap layer comprises a metal nitride, such as titanium nitride. A thickness of the cap layer can be between about 3 Angstroms and about 30 Angstroms, or between about 5 Angstroms and about 15 Angstroms.

FIG. 8 illustrates a structure/a portion of a device 800 in accordance with additional examples of the disclosure. Device or structure 800 includes a substrate 810, a metal silicide film 820, and a cap layer 830. Device or structure 800 may be substantially identical to device or structure 700, except that metal silicide film comprises a nucleation layer 820a and a bulk layer 820b. Nucleation layer 820a may comprise a metal silicide with aluminum in the range of about 0.5 at % to 7 at %, or about 1 at % to about 3 at %. Bulk layer may comprise one or more metals and silicon. In some embodiments, bulk layer comprises silicon and one or more of Nb, Ti, Mo, Ni, Co, W, Hf, Ta, or V. Metal silicide film 820 may be formed according to method 300. Nucleation layer 820a may have a thickness of about 1 Angstrom to 20 Angstroms, or about 3 Angstroms to about 15 Angstroms, or about 5 Angstroms to about 13 Angstroms. Bulk layer 820b may have a thickness of about 10 Angstroms to 280 Angstroms, or about 15 Angstroms to about 40 Angstroms, or about 20 Angstroms to 30 Angstroms. Cap layer 830 can be the same or similar to cap layer 730.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method for forming a metal silicide film, the method comprising:
providing a substrate in a reaction chamber; and
performing a thermal deposition process to form the metal silicide film on a surface of the substrate, wherein the thermal deposition process comprises at least one first deposition cycle, wherein the first deposition cycle comprises:
pulsing a first metal precursor,
pulsing a first silicon precursor, and
pulsing an organic aluminum reactant.

2. The method of claim 1, wherein the thermal deposition process comprises a plurality of second deposition cycles after the at least one first deposition cycle, wherein the second deposition cycle comprises:
pulsing a second metal precursor, and
pulsing a second silicon precursor.

3. The method of claim 1, wherein the thermal deposition process is a thermal atomic layer deposition (ALD) process.

4. The method of claim 1, wherein a thickness of the metal silicide film is between about 10 Angstroms and about 30 Angstroms.

5. The method of claim 4, further comprising depositing a cap layer directly on the metal silicide film.

6. The method of claim 1, wherein the first deposition cycle comprises, in order:
pulsing the first metal precursor,
pulsing the first silicon precursor, and
pulsing the organic aluminum reactant.

7. The method of claim 1, wherein the first metal precursor comprises one or more of Nb, Ti, Mo, Ni, Co, W, Hf, Ta, or V.

8. The method of claim 1, wherein the first metal precursor comprises a metal halide.

9. The method of claim 1, wherein the first silicon precursor comprises one or more of silane, disilane, trisilane, SiCl₄, chlorosilane, dichlorosilane, or trichlorosilane.

10. The method of claim 1, wherein the organic aluminum reactant is represented by the formula Al(R)₃, wherein each R is independently selected from H and C1-C6 alkyl groups.

11. The method of claim 10, wherein each R is independently selected from C1-C6 alkyl groups.

12. The method of claim 11, wherein the organic aluminum reactant comprises one or more of triethylaluminum, trimethylaluminum, tris-isobutylaluminum, or tris-tert-butylaluminum.

13. The method of claim 1, wherein the metal silicide film comprises less than 7 at % aluminum.

14. The method of claim 8, wherein the thermal deposition process produces a gaseous aluminum halide.

15. The method of claim 1, wherein a resistivity of the metal silicide film is less than 500 Ωcm.

16. The method of claim 1, wherein the surface comprises a metal oxide, a metal nitride, silicon oxide, silicon nitride, or bare silicon, and wherein the metal silicide film is formed directly on the surface comprising the metal oxide, the metal nitride, silicon oxide, silicon nitride, or bare silicon.

17. A method for forming a metal silicide film, the method comprising:
providing a substrate in a reaction chamber;
performing a soak process, wherein the soak process comprises providing an organic aluminum reactant to the reaction chamber for a soak period; and
performing a thermal deposition process to form the metal silicide film on a surface of the substrate, wherein the thermal deposition process comprises at least one deposition cycle, wherein the deposition cycle comprises:
pulsing a metal precursor, and
pulsing a silicon precursor.

18. The method of claim 17, wherein the organic aluminum reactant is represented by the formula Al(R)₃, wherein each R is independently selected from H and C1-C6 alkyl groups.

19. A method for forming a metal silicide film, the method comprising:
providing a substrate in a reaction chamber; and
performing a first thermal deposition process to form a nucleation layer, wherein the first thermal deposition process comprises performing a nucleation deposition cycle at least once, wherein the nucleation deposition cycle comprises:
pulsing a first metal halide precursor,
pulsing a first silicon precursor, and
pulsing an organic aluminum reactant; and
performing a second thermal deposition process to form a bulk layer on the nucleation layer, wherein the second thermal deposition process comprises performing a bulk deposition cycle a plurality of times, wherein the bulk deposition cycle comprises:
pulsing a second metal precursor, and
pulsing a second silicon precursor.

20. The method of claim 19, wherein a thickness of the nucleation layer is in the range of about 5 Angstroms to about 15 Angstroms.
